(19) United States
(12) Patent Application Publication
(10) Pub. No.: US 2026/0363136 A1
(43) Pub. Date: Nov. 12, 2026

(54) SEMICONDUCTOR STRUCTURE AND MANUFACTURING METHOD THEREOF

(71) Applicant: Taiwan Semiconductor Manufacturing Company, Ltd., Hsinchu (TW)

(72) Inventors: Hung-Pin Chang, New Taipei City (TW); Han-Yi Lu, Hsinchu City (TW); Li-Han Hsu, Hsin-Chu City (TW); Wei-Cheng Wu, Hsinchu City (TW); Der-Chyang Yeh, Hsin-Chu (TW)

(73) Assignee: Taiwan Semiconductor Manufacturing Company, Ltd., Hsinchu (TW)

(21) Appl. No.: 19/749,551

(22) Filed: Jul. 21, 2026

Related U.S. Application Data
(63) Continuation of application No. 18/595,440, filed on Mar. 5, 2024.

(51) Int. Cl. H10W 74/10; H10W 70/65; H10W 90/00; H10W 72/00; H10W 90/20

(52) U.S. Cl. CPC H10W 74/141; H10W 70/65; H10W 90/00; H10W 90/701; H10W 72/0198; H10W 74/10; H10W 90/297; H10W 90/732

(57) ABSTRACT

A manufacturing method of a semiconductor structure includes: performing a bonding process to bond a first semiconductor die to a second semiconductor die; forming an insulating encapsulant over the second semiconductor die to surround the first semiconductor die; and performing a singulation process to at least dice the insulating encapsulant and the second semiconductor die, where at least one of the first semiconductor die and the second semiconductor die comprises a first sidewall and a second sidewall laterally offset from the first sidewall.

### CROSS-REFERENCE TO RELATED APPLICATION

This application is a continuation application of and claims the priority benefit of a prior application Ser. No. 18/595,440, filed on Mar. 5, 2024, now pending. The entirety of the above-mentioned patent application is hereby incorporated by reference herein and made a part of this specification.

### BACKGROUND

The semiconductor industry has experienced rapid growth due to continuous improvement in integration density of various components, e.g., transistors, diodes, resistors, capacitors, etc. For the most part, this improvement in integration density has come from successive reductions in minimum feature size, which allows more components to be integrated into a given area. Technological advances in integrated circuit (IC) design have produced generations of ICs where each generation has smaller and more complex circuit designs than the previous generation. There is continuous effort in developing new mechanisms of forming semiconductor structures having improved electrical performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a schematic cross-sectional view of a first semiconductor die, in accordance with some embodiments.

FIG. 1B illustrates a schematic cross-sectional view of a semiconductor wafer, in accordance with some embodiments.

FIGS. 2A-2F illustrate schematic cross-sectional views of intermediate steps during a process for forming an integrated circuit package including a semiconductor structure, in accordance with some embodiments.

FIG. 3A and FIG. 3B illustrate schematic cross-sectional views of variations of a semiconductor structure, in accordance with some embodiments.

FIGS. 4A-4C illustrate schematic cross-sectional views of intermediate steps during a process for forming a semiconductor structure, in accordance with some embodiments.

FIG. 5A illustrates a schematic cross-sectional view of a first semiconductor die, in accordance with some embodiments.

FIGS. 5B-5E illustrate schematic cross-sectional views of intermediate steps during a process for forming a semiconductor structure, in accordance with some embodiments.

FIG. 6 illustrates schematic cross-sectional views of a semiconductor structure, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments discussed herein are to provide various semiconductor structures and methods for forming the same. For example, a semiconductor structure is formed by bonding a first semiconductor die to a second semiconductor die and forming an insulating encapsulant over the second semiconductor die to surround the first semiconductor die. The internal stress originates from a difference in thermal expansion among the first and second semiconductor dies and the insulating encapsulant. The thermal expansion difference is because a difference in a coefficient of thermal expansion (CTE) of the materials among the first and second semiconductor dies and the insulating encapsulant. In addition, the large CTE mismatch among the insulating encapsulant and the first and second semiconductor dies generates the stress in the semiconductor structure, especially at the bonding interface of the first and second semiconductor dies. Delamination in the bonded structure may occur or become worse during the formation of the insulating encapsulant. For example, the delamination propagates from a non-functional (or peripheral) region of the bonded structure toward a functional (or central) region of the bonded structure and such propagation may cause device failure.

According to some embodiments, a portion of the first semiconductor die corresponding to the non-functional (or peripheral) region of the bonded structure is removed prior to the formation of the insulating encapsulant. This may help to reduce the risk of delamination propagation during the formation of the insulating encapsulant. According to some embodiments, a portion of the bonded structure with non-bond areas is removed prior to the formation of the insulating encapsulant. In this manner, the likelihood of delamination propagation is eliminated. A semiconductor structure with reduced defects, improved reliability, and improved yield may be achieved. Accordingly, various embodiments provide semiconductor structures with reduced stress and improved bonding integrity.

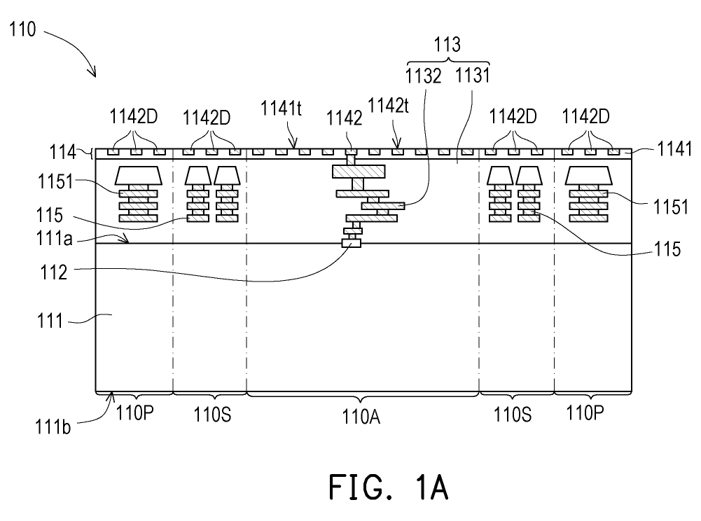

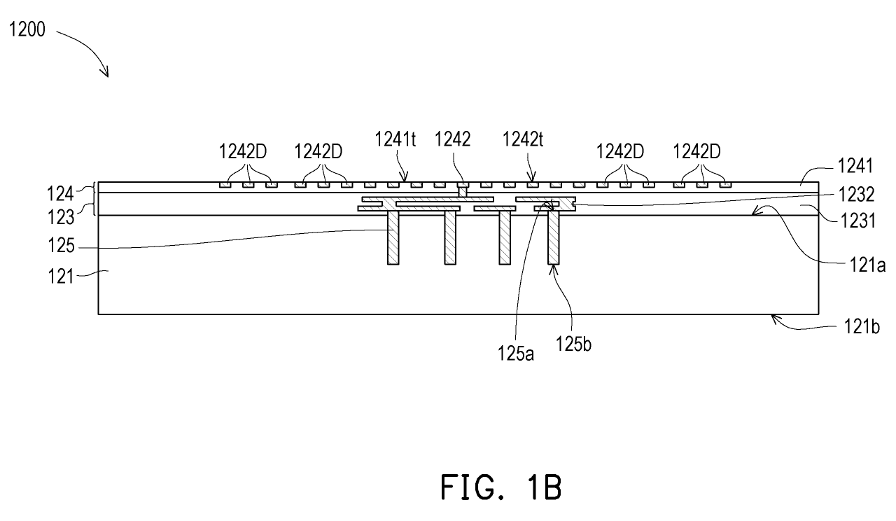

FIG. 1A illustrates a schematic cross-sectional view of a first semiconductor die, in accordance with some embodiments. It should be noted that FIG. 1A is provided for illustrative purposes only, and the first semiconductor die may utilize fewer or additional elements according to some embodiments. Referring to FIG. 1A, a first semiconductor dies 110 may be provided. The first semiconductor die 110 may be formed in a wafer (not shown), which may include different die regions that are singulated in subsequent steps to form a plurality of first semiconductor dies 110. The first semiconductor die 110 may be a logic device (e.g., central processing unit (CPU), graphics processing unit (GPU), microcontroller, etc.), a memory device (e.g., dynamic random access memory (DRAM) die, static random access memory (SRAM) die, etc.), a power management device (e.g., power management integrated circuit (PMIC) die), a radio frequency (RF) device, a sensor device, a micro-electro-mechanical-system (MEMS) device, a signal processing device (e.g., digital signal processing (DSP) die), a front-end device (e.g., analog front-end (AFE) dies), combinations thereof (e.g., a system-on-a-chip (SoC) die), or the like.

In some embodiments, the first semiconductor die 110 includes a first semiconductor substrate 111, first devices 112 formed in/on the first semiconductor substrate 111, a first interconnect structure 113 formed over the first semiconductor substrate 111 and electrically coupled to the first devices 112, and a first bonding structure 114 formed over and electrically coupled to the first interconnect structure 113. The first semiconductor substrate 111 may be a substrate of silicon, doped or undoped, or an active layer of a semiconductor-on-insulator (SOI) substrate. The first semiconductor substrate 111 may include other semiconductor materials, such as germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other suitable substrate, such as a multi-layered substrate or a gradient substrate, may be used.

The first semiconductor substrate 111 may include a front side 111a and a back side 111b opposite to the front side 111a. For example, the first devices 112 are formed at the front side 111a of the first semiconductor substrate 111. The first devices 112 may include active devices (e.g., transistors, diodes, etc.), passive devices (e.g., capacitors, resistors, inductors, etc.), a combination thereof, or the like. Although a single first device 112 is schematically illustrated in the first semiconductor die 110, it should be noted that the number and the type of the first device 112 may have a different number and type than shown.

With continued reference to FIG. 1A, the first interconnect structure 113 may be formed over the front side 111a of the first semiconductor substrate 111 and electrically coupled to the first devices 112 to form integrated circuits. The first interconnect structure 113 may include one or more first dielectric layer(s) 1131 and first metallization patterns 1132 embedded in the first dielectric layer 1131. The material of the first dielectric layer 1131 may include an oxide (e.g., silicon oxide or aluminum oxide), a nitride (e.g., silicon nitride), a carbide (e.g., silicon carbide), the like, or combinations thereof. The respective first metallization pattern 1132 may include conductive pads, conductive lines, conductive vias, combinations thereof, and/or the like. The respective first metallization pattern 1132 may be formed of a conductive material such as copper, cobalt, aluminum, gold, combinations thereof, or the like. It should be noted that the first dielectric layer 1131 and the first metallization patterns 1132 may have a different configuration than shown.

In some embodiments, the first bonding structure 114 includes one or more first bonding dielectric layer(s) 1141 and first bonding connectors 1142 embedded in the first bonding dielectric layer 1141. The first bonding dielectric layer 1141 may be formed of a material suitable for subsequent dielectric-to-dielectric bonding, such as silicon oxide, silicon oxynitride, and/or the like. The first bonding connectors 1142 may be formed of a conductive material such as copper, aluminum, or the like. The respective first bonding connector 1142 may be a conductive pad, a conductive via, a combination thereof, etc. In some embodiments, the first bonding connectors 1142 are electrically connected to the first metallization patterns 1132 of the first interconnect structure 113. It should be noted that the first bonding dielectric layer 1141 and the first bonding connectors 1142 may have a different configuration/distribution than shown. In some embodiments, a planarization process (e.g., a chemical mechanical polish (CMP) process, a grinding process, an etching process, a combination thereof, or the like) is performed such that top surfaces (1141t and 1142t) of the first bonding dielectric layer 1141 and the first bonding connectors 1142 are substantially leveled (or coplanar), within process variations.

With continued reference to FIG. 1A, the first semiconductor dies 110 may include a functional (or active) region 110A, a seal ring region 110S surrounding the functional region 110A, and a peripheral region 110P surrounding the seal ring region 110S. For example, the seal ring region 110S is between the functional region 110A and the peripheral region 110P. In some embodiments, the peripheral region 110P is viewed as a scribe line region. In some embodiments, the first devices 112, the first metallization patterns 1132, and the first bonding connectors 1142 are located within the functional region 110A. In some embodiments, both of the first bonding dielectric layer 1141 and the first dielectric layer 1131 extend across the functional region 110A and the seal ring region 110S, as well as the peripheral region 110P.

In some embodiments, one or more seal ring(s) 115 may be embedded in the first dielectric layer 1131 and within the seal ring region 110S. In some embodiments, the respective seal ring 115 is disposed in a loop encircling first metallization patterns 1132 in the functional region 110A. The seal rings 115 may include conductive vias and conductive pads vertically stacked and connected together by the conductive vias, where the conductive pads of the seal rings 115 may be at a same level as the conductive pads of the first metallization patterns 1132, and the conductive vias of the seal rings 115 may be at the same level as the conductive vias of the first metallization patterns 1132. It should be noted that the seal rings 115 may have a different configuration than shown.

In some embodiments, the first bonding structure 114 includes additional bonding connectors 1142D embedded in the first bonding dielectric layer 1141 and disposed over the seal rings 115 within the seal ring region 110S. The additional bonding connectors 1142D may be formed at the same level as the first bonding connectors 1142. In some embodiments, the additional bonding connectors 1142D are electrically and spatially isolated from the seal rings 115 at least through the first bonding dielectric layer 1141. Alternatively, the additional bonding connectors 1142D are physically connected to the underlying seal rings 115. In some embodiments, the additional bonding connectors 1142D are dummy connectors and electrically floating in the first semiconductor die 110. For example, the presence of the additional bonding connectors 1142D helps to increase the pattern uniformity and metal density, thereby facilitating the subsequent bonding process. Alternatively, the additional bonding connectors 1142D are omitted, and no conductive feature is formed over the seal ring 115 within the seal ring region 110S.

Still referring to FIG. 1A, additional seal rings 1151 may be embedded in the first dielectric layer 1131 and within the peripheral region 110P. The additional seal rings 1151 may be formed at the same level as the seal rings 115. It should be noted that the additional seal rings 1151 may have a different configuration than shown. In some embodiments, the additional bonding connectors 1142D are distributed within the peripheral region 110P and over the additional seal rings 1151. The additional bonding connectors 1142D may be electrically and spatially isolated from the additional seal rings 1151 at least through the first bonding dielectric layer 1141. The additional bonding connectors 1142D may (or may not) be physically connected to the additional seal rings 1151. Alternatively, the additional seal rings 1151 disposed within the peripheral region 110P and/or the additional bonding connectors 1142D disposed within the peripheral region 110P are omitted. The first semiconductor dies 110 may (or may not) include any metallization patterns and/or conductive features outside of the seal rings 115 (e.g., within the peripheral region 110P).

FIG. 1B illustrates a schematic cross-sectional view of a semiconductor wafer, in accordance with some embodiments. It should be noted that FIG. 1B is provided for illustrative purposes only, and the semiconductor wafer may utilize fewer or additional elements according to some embodiments. Referring to FIG. 1B, a semiconductor wafer 1200 may be provided. The semiconductor wafer 1200 may include a second semiconductor substrate 121 having a front side 121a and a back side 121b, a second interconnect structure 123 formed over the front side 121a of the second semiconductor substrate 121, a second bonding structure 124 formed over the second interconnect structure 123, and through vias 125 formed in the second semiconductor substrate 121 and extending into the second interconnect structure 123.

The second semiconductor substrate 121 may be a bulk semiconductor substrate, a SOI substrate, a multi-layered semiconductor substrate, or the like. The material of the second semiconductor substrate 121 may be selected from the same group of candidate materials for forming the first semiconductor substrate 111 discussed in FIG. 1A. The second semiconductor substrate 121 may be doped or undoped. In some embodiments, the semiconductor wafer 1200 is free of active/passive devices, and the second semiconductor substrate 121 does not include active/passive devices formed at the front side 121a. In some embodiments, second devices (e.g., transistors, diodes, capacitors, resistors, inductors, combinations thereof, and/or the like; not shown) are formed at the front side 121a of the second semiconductor substrate 121. The second interconnect structure 123 may include one or more second dielectric layer(s) 1231 and second metallization patterns 1232 embedded in the second dielectric layer 1231. The second dielectric layer 1231 and the second metallization patterns 1232 may be respectively similar to the first dielectric layer 1131 and the first metallization patterns 1132 which are described in FIG. 1A, and thus the details thereof are not repeated herein.

The second bonding structure 124 may be formed over and electrically connected to the second interconnect structure 123. For example, the second bonding structure 124 includes one or more second bonding dielectric layer(s) 1241 and second bonding connectors 1242 embedded in the second bonding dielectric layer 1241. The second bonding connectors 1242 may be electrically connected to the second metallization patterns 1232. The second bonding dielectric layer 1241 and the second bonding connectors 1242 may be respectively similar to the first bonding dielectric layer 1141 and the first bonding connectors 1142 which are described in FIG. 1A, and thus the details thereof are not repeated herein. In some embodiments, the second bonding structure 124 includes additional bonding connectors 1242D embedded in the second bonding dielectric layer 1241. The additional bonding connectors 1242D may be formed at the same level as the second bonding connectors 1242. In some embodiments, the additional bonding connectors 1242D are dummy connectors and electrically isolated from the second bonding connectors 1242. The additional bonding connectors 1242D may be electrically floating in the semiconductor wafer 1200. In some embodiments, the additional bonding connectors 1242D are subsequently bonded to the additional bonding connectors 1142D of the first semiconductor die 110. A planarization process (e.g., a CMP process, a grinding process, an etching process, a combination thereof, or the like) is optionally performed on the second bonding structure 124, such that top surfaces (1241t and 1242t) of the second bonding dielectric layer 1241, the second bonding connectors 1242, and the additional bonding connectors 1142D are substantially leveled (or coplanar), within process variations.

The through vias 125 may be formed in the second semiconductor substrate 121 by depositing one or more diffusion barrier layer(s) or isolation layer(s), depositing a seed layer, and depositing a conductive material (e.g., tungsten, titanium, aluminum, copper, any combinations thereof and/or the like) into the trenches of the second semiconductor substrate 121. For example, the respective through via 125 includes a first end 125a physically and electrically connected to one of the second metallization patterns 1232 and a second end 125b opposite to the first end 125a, where the second end 125b may be buried in the second semiconductor substrate 121 at this stage.

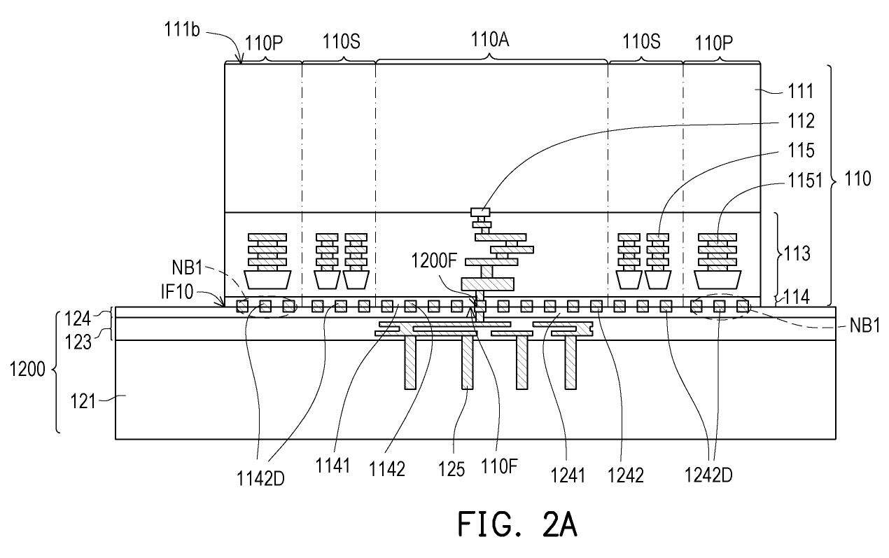

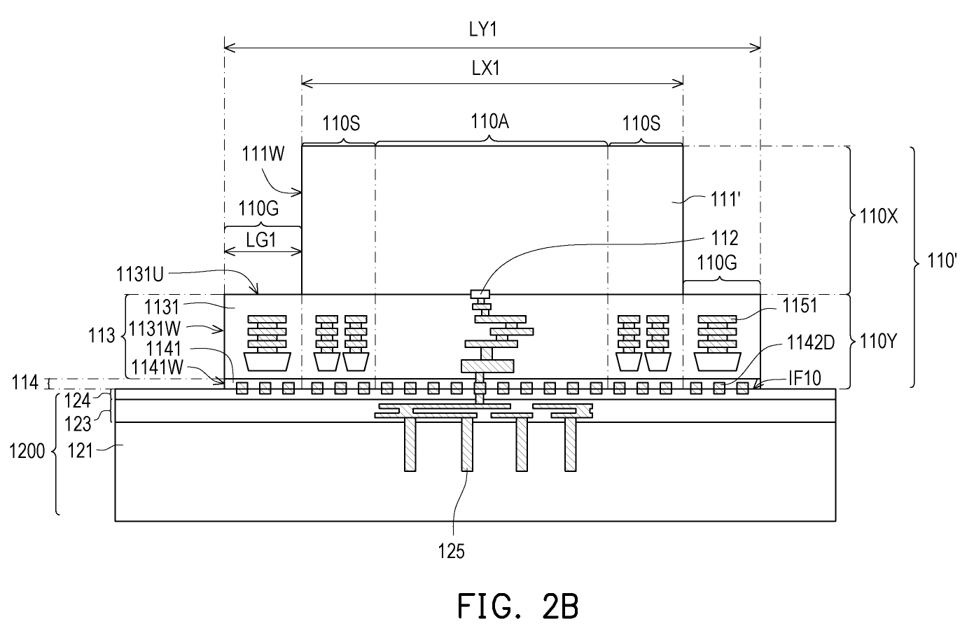

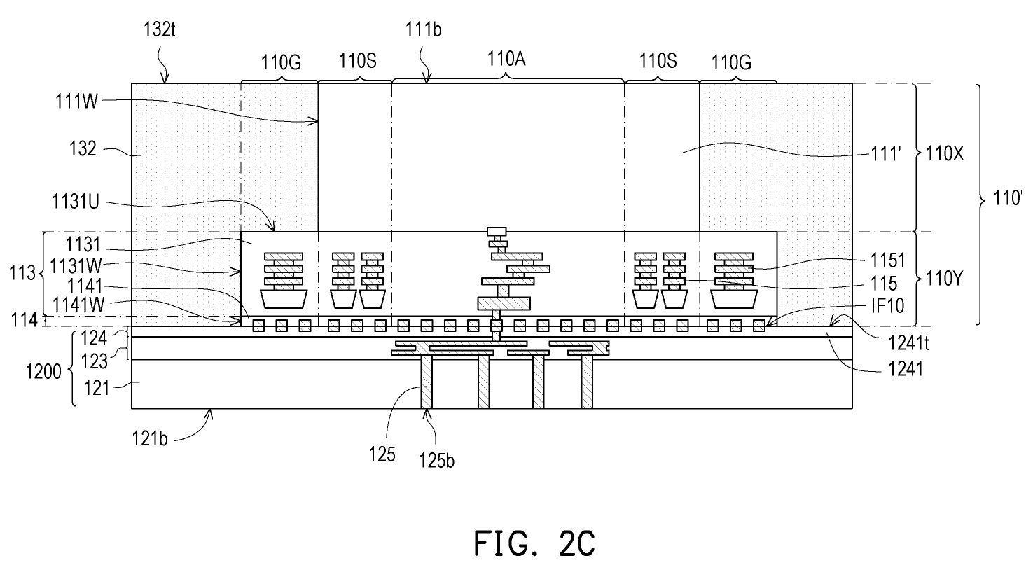

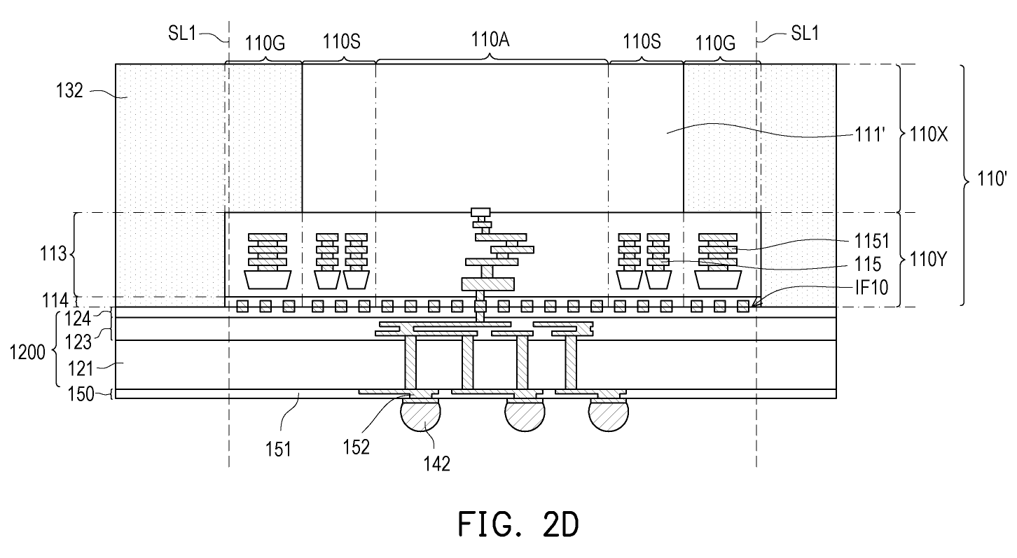

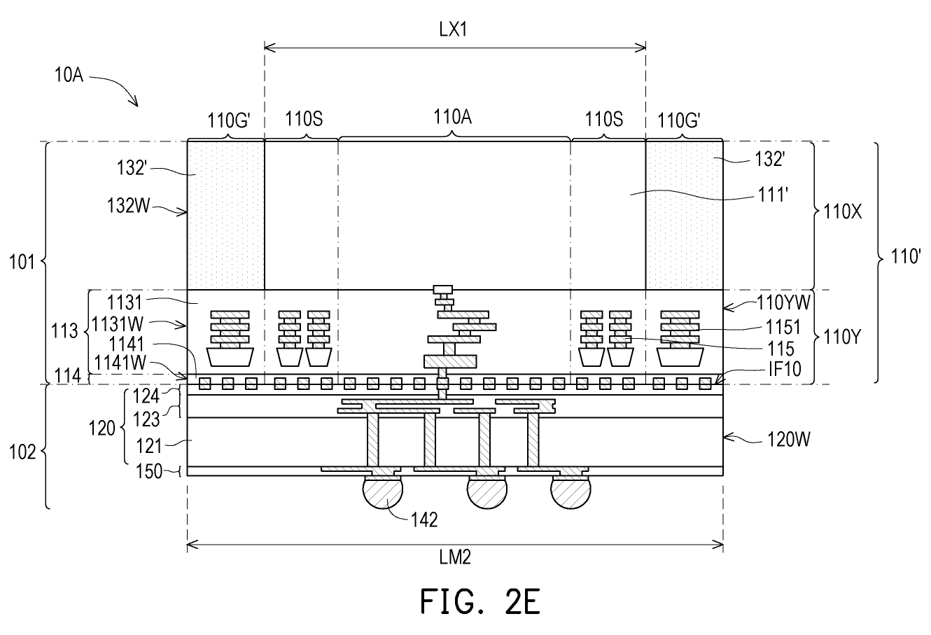

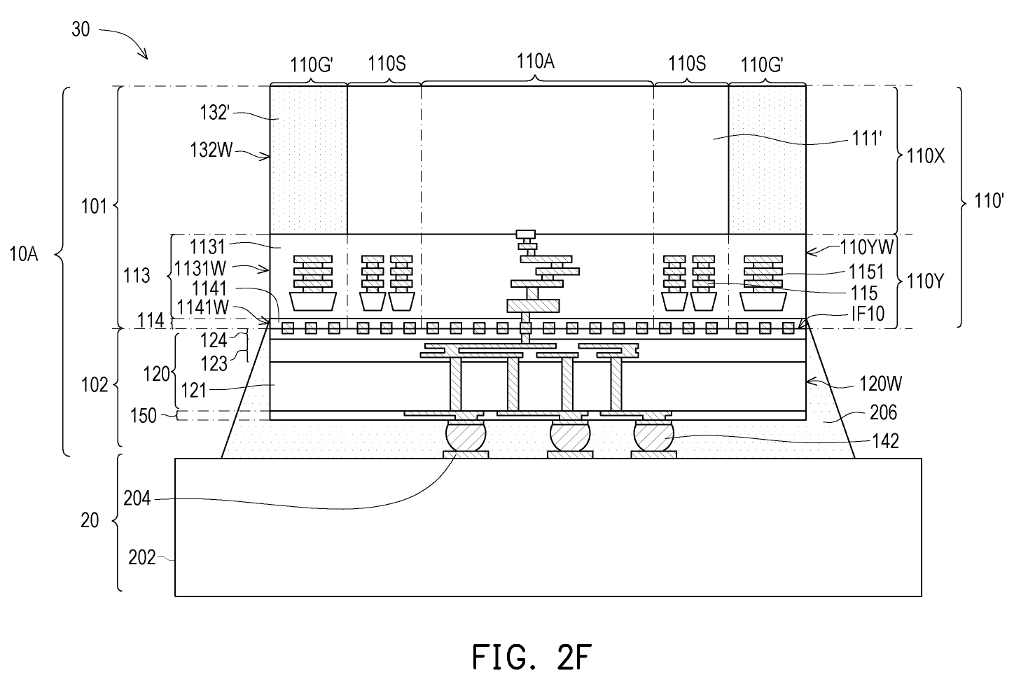

FIGS. 2A-2F illustrate schematic cross-sectional views of intermediate steps during a process for forming an integrated circuit (IC) package including a semiconductor structure, in accordance with some embodiments. Unless specified otherwise, the first semiconductor die 110 and the semiconductor wafer 1200 in these embodiments are essentially the same as the like components, which are denoted by like reference numerals in the embodiments shown in FIGS. 1A-1B. The details regarding the first semiconductor die 110 and the semiconductor wafer 1200 may be found in the discussion of the previous embodiments.

Referring to FIG. 2A and with reference to FIGS. 1A-1B, the first semiconductor die 110 may be bonded to the semiconductor wafer 1200. Although a single first semiconductor dies 110 is illustrated, any number of the first semiconductor die 110 may be bonded to the semiconductor wafer 1200. In some embodiments, the first semiconductor dies 110 and the semiconductor wafer 1200 are directly bonded in a face-to-face manner by dielectric-to-dielectric bonding and metal-to-metal bonding. For example, the front side 110F of the first semiconductor die 110 is bonded to the front side 1200F of the semiconductor wafer 1200. In some embodiments, the first bonding dielectric layer 1141 is fused to the second bonding dielectric layer 1241 through dielectric-to-dielectric bonding, and dielectric-to-dielectric (e.g., oxide-to-oxide) bonds may be formed therebetween. The first bonding connectors 1142 may be directly bonded to the second bonding connectors 1242 through metal-to-metal bonding, and metal-to-metal (e.g., copper-to-copper) bonds may be formed therebetween. In some embodiments, dielectric-to-metal (e.g., oxide-to-copper; not individually shown) bonds are formed at the bonding interface IF10 of the first semiconductor die 110 and the semiconductor wafer 1200. In some embodiments, the bonding interface IF10 is free of solder material. The bonding interface IF10 may be substantially flat and planar, within process variations.

In some embodiments, the bonding of the first semiconductor die 110 and the semiconductor wafer 1200 includes a pre-bonding process and an annealing process. During the pre-bonding process, a force may be applied to press the first semiconductor die 110 against the semiconductor wafer 1200. The bonding strength of the first and second bonding dielectric layers (1141 and 1241) may be improved in the annealing process, in which the first and second bonding dielectric layers (1141 and 1241) are annealed at a high temperature. In some embodiments, after the bonding process, the first and second bonding connectors (1142 and 1242) are directly connected to one another with a one-to-one correspondence. In some embodiments, the additional bonding connectors (1142D and 1242D) are directly bonded to one another with a one-to-one correspondence.

It is appreciated that a problem that affects the electrical reliability of the bonded structure is the adhesion between the first semiconductor die 110 and the semiconductor wafer 1200. Poor adhesion may lead to delamination. In some cases, during the bonding process, the first and second bonding connectors may be expanded under the annealed temperature and apply stresses to the surrounding the first and second bonding dielectric layers and hence cause delamination. For example, after the bonding process, non-bond areas NB1 exist at the bonding interface IF10 (e.g., corresponding to the peripheral region 110P). During subsequent processing steps (e.g., the formation of an insulating encapsulant described in FIG. 2C), the large CTE mismatch between the insulating encapsulant and the semiconductor die/wafer may generate stress in the resulting structure, especially at the interface between the insulating encapsulant and the semiconductor die/wafer. Under the thermal mismatch stresses, the non-bond areas NB1 may be enlarged, and cracks (if exist) may extend toward the functional region 110A. This may cause the first semiconductor die and the semiconductor wafer to separate and render the resulting structure to be non-functional or failure. Thus, in the manufacture of the semiconductor structure, it is important to prevent the bonding interface from delaminating and prevent any cracks extending into the functional region 110A. As described in greater detail below, by partially removing the bonded structure, the bonding interface stress during the formation of the insulating encapsulant may be reduced, and the adhesion of the bonded structure may be improved.

Referring to FIG. 2B and with reference to FIG. 2A, a portion of the first semiconductor die 110 in the peripheral region 110P may be removed by any suitable method to form a first semiconductor die 110’ including a ledge portion 110G. For example, a photoresist (not shown) is formed on the bonded structure and covers the back side 111b of the first semiconductor substrate 111 by spin-coating, spray-coating, or any suitable deposition process, and then a patterning process is performed on the photoresist to form an opening by lithography, or the like, where the opening of the photoresist may accessibly expose a portion of the first semiconductor substrate 111 to be removed. Next, the portion of the first semiconductor substrate 111 exposed by the opening of the photoresist may be removed by, for example, plasma etching, laser grooving, and/or any suitable removal process. In some embodiments, not only the portion of the first semiconductor substrate 111 in the peripheral region 110P which is directly above the non-bond areas NB1 (if exist), but also a portion of the first dielectric layer 1131 underlying the portion of the first semiconductor substrate 111 may be removed. Afterwards, the photoresist may be removed.

As shown in FIG. 2B, the first semiconductor die 110’ may include a first portion 110X and a second portion 110Y connected to the first portion 110X and bonded to the semiconductor wafer 1200. The first portion 110X may be the rest of the first semiconductor substrate 111’, and the second portion 110Y may include the first interconnect structure 113 and the underlying first bonding structure 114. The first interconnect structure 113 and the underlying first bonding structure 114 may be laterally protruded from the first semiconductor substrate 111’. The portions of the first interconnect structure 113 and the underlying first bonding structure 114 protruded from the first semiconductor substrate 111’ may be viewed as the ledge portion 110G. The additional seal ring 1151 and the additional bonding connectors 1142D may be disposed in the ledge portion 110G. For example, the first portion 110X has a lateral dimension LX1 less than a lateral dimension LY1 of the second portion 110Y. The difference of the lateral dimensions (LY1 and LX1) may be the lateral dimension LG1 of the ledge portion 110G. It should be noted that the lateral dimensions (LX1, LY1, and LG1) may vary depending on the process and product requirements and construe no limitation in the disclosure. In some embodiments, the sidewall 111W of the first semiconductor substrate 111’ is laterally displaced from the sidewall 1131W of the first dielectric layer 1131 and the sidewall 1141W of the first bonding dielectric layer 1141, where the sidewall 1141W is substantially aligned (or coplanar) with the sidewall 1131W, within process variations. In some embodiments, an upper surface 1131U of the first dielectric layer 1131 connected to the sidewall 1131W is accessibly revealed at this stage.

Referring to FIG. 2C and with reference to FIG. 2B, an insulating encapsulant 132 may be formed on the semiconductor wafer 1200 to cover the first semiconductor die 110’. In some embodiments, the insulating encapsulant 132 is formed of a molding material or compound and may be formed by compression molding, transfer molding, or the like. The molding material includes a polymer material and optionally includes fillers (not individually illustrated), where the fillers may be particles of silica or the like, and the polymer material may be an epoxy or the like. The fillers mixed in the polymer material may provide mechanical strength and thermal dispersion for the insulating encapsulant 132. For example, the insulating material is formed over the top surface 1241t of the second bonding dielectric layer 1241 of the semiconductor wafer 1200, and the first semiconductor die 110’ may be buried or covered by the insulating material. The insulating material may then be cured to form the insulating encapsulant 132.

A planarization process (e.g., CMP, grinding, etching, combinations thereof, or the like) is optionally performed to planarize the insulating encapsulant 132. The planarization process may (or may not) remove the insulating encapsulant 132 on the back side 111b of the first semiconductor substrate 111’. In some embodiments, the back side 111b of the first semiconductor die 110’ is accessibly exposed by the planarization of the insulating encapsulant 132, and surfaces (e.g., 111b and 132t) of the first semiconductor die 110’ and the insulating encapsulant 132 are substantially leveled (or coplanar), within process variations. In some embodiments, the insulating encapsulant 132 laterally covers the first and second portions (110X and 110Y) of the first semiconductor die 110’. The insulating encapsulant 132 may be in physical contact with the sidewall 111W of the first semiconductor substrate 111’, the upper surface 1131U and the sidewall 1131W of the first dielectric layer 1131, and the sidewall 1141W of the first bonding dielectric layer 1141. By partially removing the first semiconductor die 110 to form the first semiconductor die 110’ having the ledge portion 110G, bonding interface stress, especially in the peripheral region 110P of the first semiconductor die 110, may be reduced during the formation of the insulating encapsulant 132. In this manner, even if the non-bond areas (e.g., NB1 labeled in FIG. 2A) and/or cracks exist in the bonded structure, stress in the bonded structure may be relaxed during the formation of the insulating encapsulant 132, thereby preventing delamination/cracks from occurring, becoming more severe, and/or extending into the functional region 110A.

With continued reference to FIG. 2C and FIG. 2B, a thinning process (e.g., grinding, CMP, etching, combinations thereof, or the like) may be performed on the back side of the semiconductor wafer 1200. For example, the back side 121b of the second semiconductor substrate 121 is thinned down until at least a portion of the second ends 125b of the through vias 125 is accessibly exposed. In some embodiments, the thinning process is performed after the formation of the insulating encapsulant 132. Since the through vias 125 penetrate through the second semiconductor substrate 121, the through vias 125 may be viewed as through-substrate vias (TSVs) 125.

Referring to FIG. 2D and with reference to FIG. 2C, a plurality of conductive terminals 142 may be formed over the back side 121b of the second semiconductor substrate 121 and electrically connected to the TSVs 125. The conductive terminals 142 may be controlled collapse chip connection (C4) bumps, ball grid array (BGA) connectors, solder balls, metal pillars, micro-bumps, electroless nickel-electroless palladium-immersion gold (ENEPIG) formed bumps, or the like. The conductive terminals 142 may include a conductive material such as solder, copper, aluminum, gold, nickel, silver, palladium, tin, the like, or a combination thereof. In some embodiments, the conductive terminals 142 are formed by forming a solder material; and performing a reflow process on the solder material to form desired bump shapes. In some embodiment, the respective conductive terminal 142 includes a pillar portion (e.g., a copper pillar) and a cap portion formed on the pillar portion, where the pillar portion has a substantially vertical sidewall and the cap portion has a bump profile.

In some embodiments, before forming the conductive terminals 142, a redistribution structure 150 is formed on the back side 121b of the second semiconductor substrate 121 and the second ends 125b of the TSVs 125. For example, the redistribution structure 150 includes one or more dielectric layer(s) 151 and conductive patterns (or redistribution wirings) 152 formed in the dielectric layer 151 and electrically connected to the TSVs 125. The dielectric layer 151 may be formed of any suitable dielectric material such as polybenzoxazole (PBO), polyimide, a benzocyclobuten (BCB), a combination thereof, or the like. The conductive patterns 152 may include conductive pads, conductive vias, conductive lines, a combination thereof, or the like, and may be formed of any suitable conductive material such as copper, cobalt, aluminum, gold, combinations thereof, or the like. In some embodiments, the conductive patterns 152 include under bump metallization (UBM) pads, and the conductive terminals 142 may be formed on the UBM pads. Alternatively, the redistribution wirings of the redistribution structure 150 is omitted. In such cases, the UBM pads are directly formed on the second ends 125b of the TSVs 125, and the conductive terminals 142 are formed on the UBM pads to be electrically coupled to the TSVs 125.

Referring to FIG. 2E and with reference to FIG. 2D, a singulation process is optionally performed by cutting along scribe lanes SL1 to form individual semiconductor structure 10A. For example, the semiconductor structure 10A includes a first tier 101 stacked upon a second tier 102, where the first tier 101 includes the first semiconductor die 110’ and the insulating encapsulant 132 covering the first semiconductor die 110’, and the second tier 102 includes the second semiconductor die 120 formed by singulating the semiconductor wafer 1200, the redistribution structure 150 underlying the second semiconductor die 120, and the conductive terminals 142 electrically coupled to the second semiconductor die 120 through the redistribution structure 150. In some embodiments, the second semiconductor die 120 is viewed as an interposer. In some embodiments, the scribe lanes SL1 vertically pass through the periphery (e.g., the ledge portion 110G or the second portion 110Y) of the first semiconductor die 110’. For example, at least the edge of the ledge portion 110G is removed after the singulation process to form the ledge portion 110G’. The portion of the insulating encapsulant 132 laterally surrounding the second portion 110Y of the first semiconductor die 110’ may be removed during the singulation process, and the rest of the insulating encapsulant 132 laterally surrounding the first portion 110X of the first semiconductor die 110’ may remain after the singulation process. After the singulation process, the maximum lateral dimension LX1 of the first semiconductor substrate 111’ of the first semiconductor die 110’ is less than the maximum lateral dimension LM2 of the second semiconductor die 120. The maximum lateral dimension of the first interconnect structure 113 may be substantially equal to the maximum lateral dimension LM2 of the second semiconductor die 120.

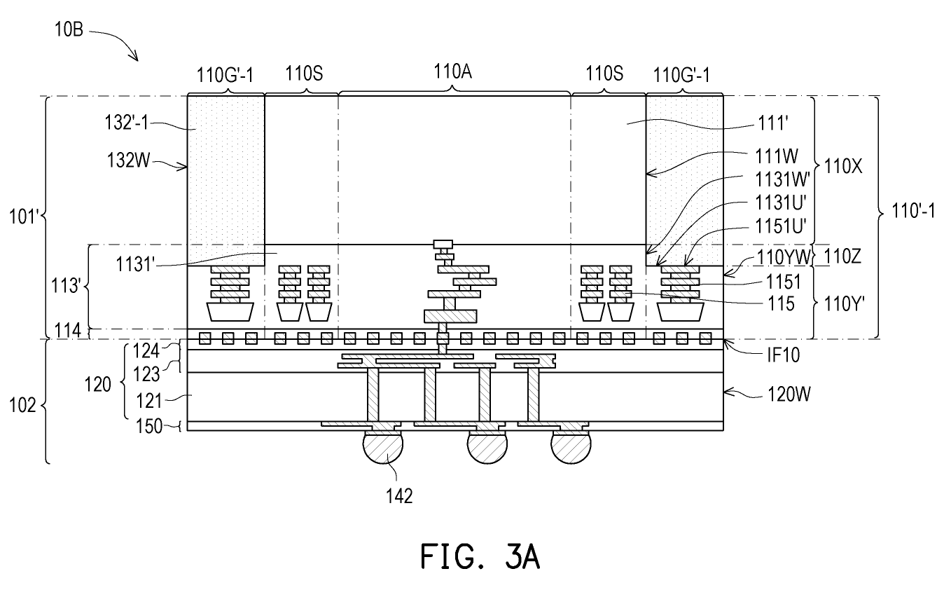

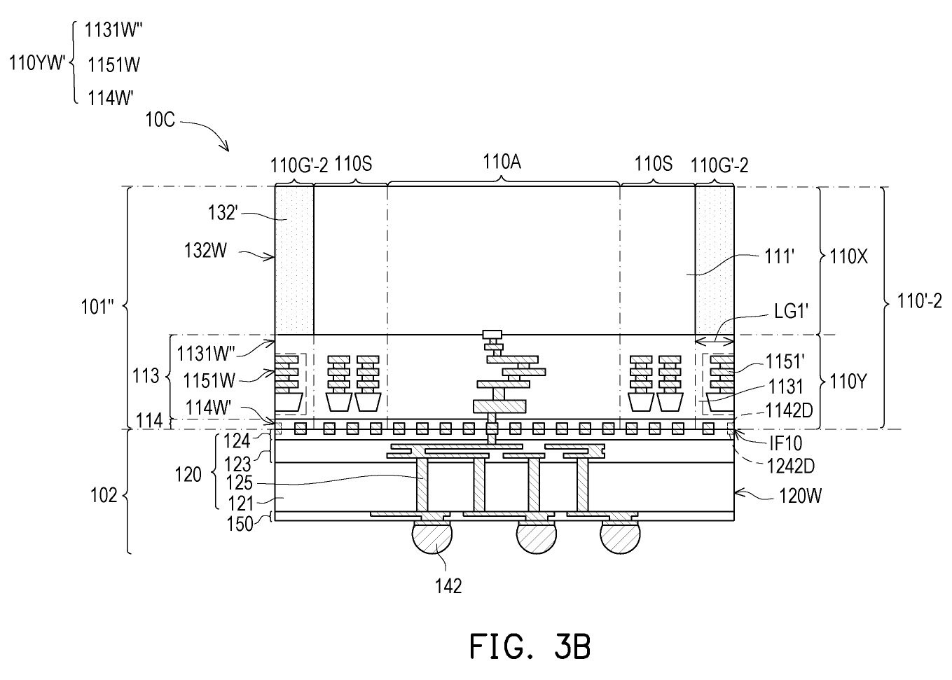

As shown in FIG. 2E, the singulated insulating encapsulant 132’ may have a singulated sidewall 132W substantially aligned (or coplanar) with the singulated sidewall 110YW of the second portion 110Y of the first semiconductor die 110’ and the singulated sidewall 120W of the second semiconductor die 120, within process variations. For example, the singulated sidewall 110YW of the second portion 110Y of the first semiconductor die 110’ includes the singulated sidewall 113W’ of the first interconnect structure 113 and the singulated sidewall 114W’ of the first bonding structure 114. The locations of the scribe lanes SL1 may be adjusted depending on process and product requirements. For example, the scribe lanes SL1 only pass through the insulating encapsulant 132 and the underlying semiconductor wafer 1200 without passing through the first semiconductor die 110’. In such cases, the first and second portions (110X and 110Y) of the first semiconductor die 110’ remain laterally covered by the singulated insulating encapsulant. In alternative embodiments, the scribe lanes SL1 pass through the ledge portion 110G, and the additional seal rings 1151 in the ledge portion 110G are singulated as will be described later in accompanying with FIG. 3B.

Referring to FIG. 2F and with reference to FIG. 2E, the semiconductor structure 10A is optionally mounted on a package substrate 20 using the conductive terminals 142 to form an integrated circuit (IC) package 30. The package substrate 20 may include a substrate 202, which may be made of a semiconductor material such as silicon, germanium, diamond, or the like. Alternatively, compound materials such as silicon germanium, silicon carbide, gallium arsenic, indium arsenide, indium phosphide, silicon germanium carbide, gallium arsenic phosphide, gallium indium phosphide, combinations of these, and the like, may also be used. The substrate 202 may be a SOI substrate. Alternatively, the substrate 202 includes an insulating core (not individually illustrated) such as a fiberglass reinforced resin core (e.g., FR4), BT resin core or includes printed circuit board (PCB) materials or films. Build up films (e.g., Ajinomoto build-up film or other laminates; not individually illustrated) may be used for the substrate 202. The substrate 202 may include active and/or passive devices (not illustrated) to generate the functional requirements of the design for the system.

The package substrate 20 may include contact pads 204 formed in/on the substrate 202. The conductive terminals 142 may be reflowed to attach the semiconductor structure 10A to the contact pads 204 of the package substrate 20. After coupling the conductive terminals 142 to the contact pads 204, the semiconductor structure 10A may be electrically coupled to the package substrate 20. In some embodiments, the IC package 30 includes an underfill 206 formed in a gap between the semiconductor structure 10A and the package substrate 20. The underfill 206 may laterally surround the conductive terminals 142 for protection. The underfill 206 may be formed by a capillary flow process after the semiconductor structure 10A is attached or may be formed by a suitable deposition method before the semiconductor structure 10A is attached. The underfill 206 may be a continuous material extending from the gap between the package substrate 20 and the semiconductor structure 10A. In some embodiments, the underfill 206 extends upward to be in physical contact with the singulated sidewall 120W of the second semiconductor die 120. Depending on the applied amount of the underfill 206, in some embodiments, the underfill 206 extends upward to be in physically contact with the singulated sidewall 110YW of the first semiconductor die 110’. The perimeter of the bonding interface IF10 may be surrounded by the underfill 206. In some other embodiments, the underfill 206 extends upward to be in physically contact with the singulated sidewall 132W of the singulated insulating encapsulant 132’. The above examples are provided for illustrative purposes only, and the IC package 30 may include fewer or additional elements, in other embodiments.

FIG. 3A and FIG. 3B illustrate schematic cross-sectional views of variations of a semiconductor structure, in accordance with some embodiments. Unless specified otherwise, the materials and the formation methods of the components in these embodiments are essentially the same as the like components, which are denoted by like reference numerals in the embodiments shown in FIG. 2E. The details of the components shown in FIGS. 3A-3B may be found in the discussion of the previous embodiments.

Referring to FIG. 3A and with reference to FIG. 2E, a semiconductor structure 10B shown in FIG. 3A is similar to the semiconductor structure 10A shown in FIG. 2E, except that the first semiconductor die 110’-1 of the first tier 101’ includes a third portion 110Z vertically interposed between the first portion 110X and the second portion 110Y’, and the additional seal ring 1151 in the second portion 110Y’ is in direct contact with the simulated insulating encapsulant 132’-1. The third portion 110Z may have a lateral dimension substantially equal to the lateral dimension of the first portion 110X and less than the lateral dimension of the second portion 110Y’. For example, the third portion 110Z is a part of the first interconnect structure 113’, and the second portion 110Y’ includes the rest part of the first interconnect structure 113’ and the underlying first bonding structure 114. The second portion 110Y’ may be laterally protruded from the third portion 110Z, and the protruded part may be viewed as the ledge portion 110G’-1. The additional seal ring 1151 may be disposed in the second portion 110Y’ and in the ledge portion 110G’-1.

In some embodiments, during the process of partially removing the first semiconductor die 110 as described in FIG. 2B, a portion of the first interconnect structure 113 directly underlying the portion of the first semiconductor substrate 111 in the peripheral region 110P (labeled in FIG. 2A) is also removed until at least a portion of the additional seal ring 1151 is accessibly exposed by the first dielectric layer 1131’. The additional seal ring 1151 may act as a stop layer during the removal process. In some embodiments, the upper surface 1131U’ of the first dielectric layer 1131’ and the upper surface 1151U’ of the additional seal ring 1151 are substantially leveled (or coplanar), within process variations. In some embodiments, the upper surface 1151U’ of the additional seal ring 1151 is slightly protruded from the upper surface 1131U’ of the first dielectric layer 1131’. The sidewall 1131W’ of the first dielectric layer 1131’ connected to the upper surface 1131U’ may be substantially leveled (or coplanar) with the sidewall 111W of the first semiconductor substrate 111’. The sidewall 1131W’ of the first dielectric layer 1131’ may be viewed as a sidewall of the third portion 110Z. The singulated sidewall 110YW of the second portion 110Y’ may be laterally displaced from the sidewall 1131W’ of the third portion 110Z.

As shown in FIG. 3A, the first tier 101’ of the semiconductor structure 10B may include the singulated insulating encapsulant 132’-1 extending along the sidewalls (111W and 1131W’) of the first portion 110X and the third portion 110Z. The singulated insulating encapsulant 132’-1 may be in physical contact with the upper surface 1131U’ of the first dielectric layer 1131’ and the upper surface 1151U’ of the additional seal ring 1151. After the singulation process, the singulated sidewall 132W of the singulated insulating encapsulant 132’-1 may be substantially aligned (or coplanar) with the singulated sidewall 110YW of the second portion 110Y’ and the singulated sidewall 120W of the second semiconductor die 120. The semiconductor structure 10B is optionally mounted on the package substrate 20 (see FIG. 2F) using the conductive terminals 142 to form an IC package.

Referring to FIG. 3B and with reference to FIG. 2E, a semiconductor structure 10C shown in FIG. 3B is similar to the semiconductor structure 10A shown in FIG. 2E, except that the second portion 110Y of the first semiconductor die 110’-2 may have a singulated sidewall 110YW’ including the singulated sidewall 1151W of the additional seal ring 1151’. For example, the scribe lanes SL1 (labeled in FIG. 2D) pass through the additional seal ring 1151 in the ledge portion 110G of the first semiconductor die 110’. In such cases, during the singulation process, the cutting tool (e.g., a blade or the like) may cut through insulating encapsulant 132, the first dielectric layer 1131, the additional seal ring 1151, and the first bonding structure 114 so as to form the first tier 101”. In some embodiments, the scribe lanes SL1 also pass through the additional bonding connectors (1142D and 1242D) directly below the singulated additional seal ring 1151 in the ledge portion 110G. In such cases, the singulated sidewalls of the additional bonding connectors (1142D and 1242D) may be exposed at an outer sidewall of the semiconductor structure 10C. Alternatively, no additional bonding connectors (1142D and 1242D) are singulated. Thus, the singulated bonding connectors (1142D and 1242D) in FIG. 3B are illustrated in the dashed lines to indicate they may (or may not) exist.

After the singulation process, the singulated sidewall 110YW’of the second portion 110Y of the first semiconductor die 110’-2 may include the singulated sidewall 1131W” of the first dielectric layer 1131, the singulated sidewall 1151W of the additional seal ring 1151’, and the singulated sidewall 114W’ of the first bonding structure 114 that are substantially aligned (or coplanar) with one another, within process variations. The singulated sidewall 110YW’of the second portion 110Y of the first semiconductor die 110’-2 may be substantially aligned (or coplanar) with the singulated sidewall 132W of the singulated insulating encapsulant 132’ and the singulated sidewall 120W of the second semiconductor die 120, within process variations. The semiconductor structure 10C is optionally mounted on the package substrate 20 (see FIG. 2F) using the conductive terminals 142 to form an IC package.

It is appreciated that depending on the locations of the scribe lanes SL1 (labeled in FIG. 2D), the singulated sidewall of the semiconductor structure may have a different configuration than shown. For example, the lateral dimension LG1’ of the ledge portion 110G’-2 is non-zero. In some embodiments, the lateral dimension LG1’ is greater than 1μm. Other values are also possible. In some embodiments, the scribe lanes SL1 (labeled in FIG. 2D) pass through both of conductive pads and conductive vias of the respective additional seal ring 1151. As illustrated by FIG. 3B, the singulated sidewall 1151W of the respective additional seal ring 1151’ may thus include the sidewalls of the conductive pads and the sidewalls of the conductive vias that are substantially aligned (or coplanar) with one another, within process variations. In some other embodiments, the scribe lanes SL1 (labeled in FIG. 2D) pass through the conductive pads of the respective additional seal ring 1151 without passing through the conductive vias of the respective additional seal ring 1151. In such cases, the singulated sidewall 1151W of the respective additional seal ring 1151’ may include the sidewalls of the conductive pads, and the sidewalls of the conductive pads of the additional seal ring 1151’ and the segmental sidewalls of the first dielectric layer 1131 are vertically and alternately arranged. In alternative embodiments, the scribe lanes SL1 (labeled in FIG. 2D) pass through the first dielectric layer 1131, and the additional seal rings 1151 are outside the scribe lanes SL1. In such cases, during the singulation process, the additional seal rings 1151 are completely removed. Accordingly, the additional seal rings 1151’ are encircled by the dashed boxes outlined in FIG. 3B to indicate that those may (or may not) exist in the ledge portion of the first semiconductor die 110’-2.

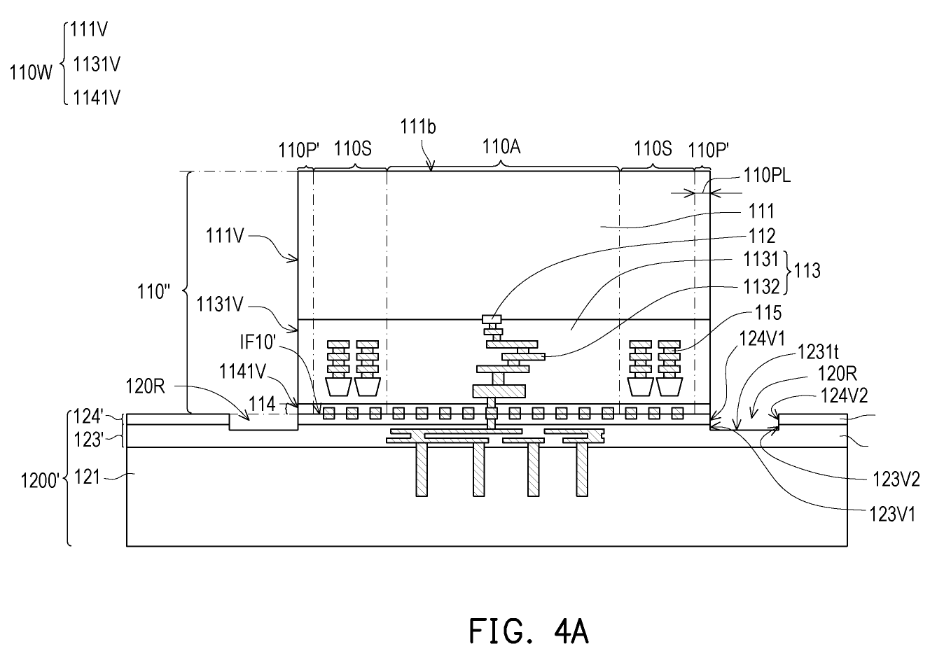

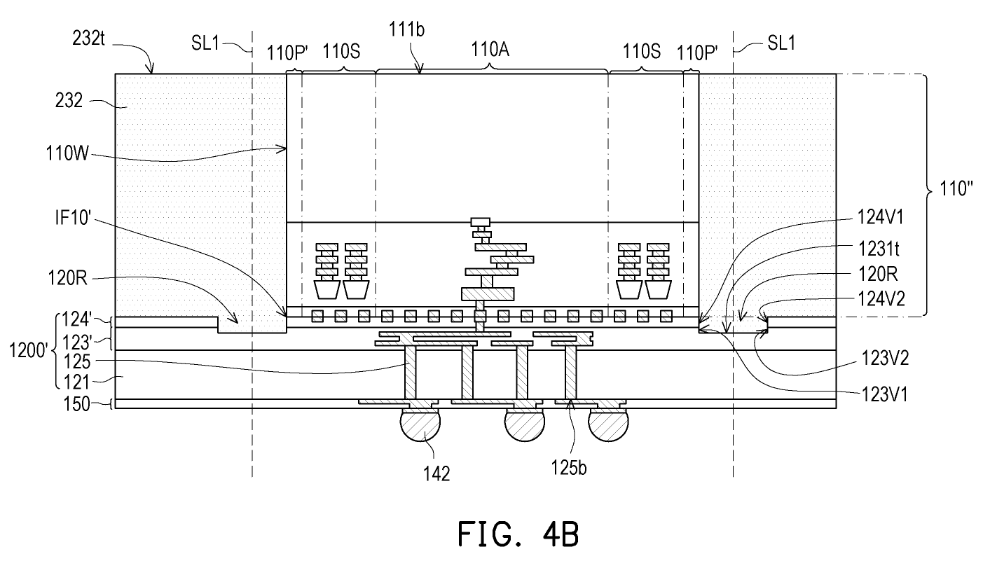

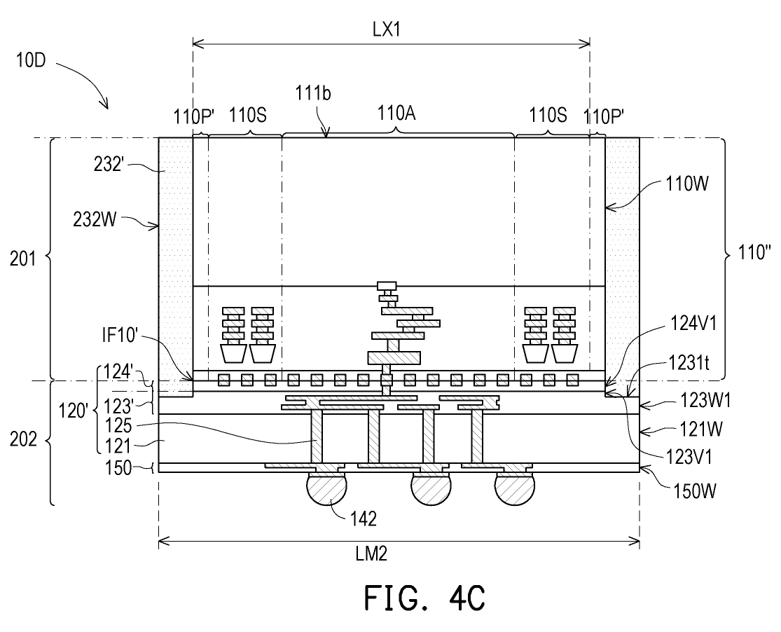

FIGS. 4A-4C illustrate schematic cross-sectional views of intermediate steps during a process for forming a semiconductor structure, in accordance with some embodiments. Unless specified otherwise, the materials and the formation methods of the components in these embodiments are essentially the same as the like components, which are denoted by like reference numerals in the embodiments shown in FIGS. 2A through 2E. The details regarding the formation process and the materials of the components shown in FIGS. 4A-4C may be found in the discussion of the previous embodiments.

Referring to FIG. 4A and with reference to FIGS. 2A-2B, the first semiconductor die 110 may be bonded to the semiconductor wafer 1200 as described in FIG. 2A. After the bonding process, a portion of the bonded structure may be removed by any suitable methods (e.g., plasma etching, laser grooving, combinations thereof, other patterning process, or the like). For example, the peripheral region 110P of the first semiconductor die 110 is partially (or entirely) removed to form a first semiconductor die 110” having a continuous sidewall 110W. The continuous sidewall 110W may include the sidewall 111V of the first semiconductor substrate 111, the sidewall 1131V of the first dielectric layer 1131, and the sidewall 1141V of the first bonding structure 114. For example, the sidewalls (111V, 1131V, and 1141V) are substantially aligned (or coplanar) with one another, within process variations.

In some embodiments, a portion of the first semiconductor die 110 corresponding to the non-bond areas NB1 (if exist; labeled in FIG. 2A) is removed. In some embodiments, the first semiconductor substrate 111, the first interconnect structure 113 underlying the first semiconductor substrate 111, and the first bonding structure 114 underlying the first interconnect structure 113 that are within the peripheral region 110P are partially (or fully) removed. In some embodiments, the additional seal rings 1151 disposed in the peripheral region 110P and the additional bonding connectors 1142D (if exist) directly underneath the additional seal rings 1151 are also removed. Alternatively, the additional seal rings 1151 and/or the additional bonding connectors 1142D within the peripheral region 110P may be partially removed. In such cases, a sidewall of the additional seal rings 1151 and/or a sidewall of the additional bonding connectors 1142D may be exposed at an outer sidewall of the first semiconductor die 110”. For example, the peripheral region 110P of the first semiconductor die 110 is partially removed, and the lateral dimension 110PL of the remaining peripheral region 110P’ is non-zero. For example, the lateral dimension 110PL of the remaining peripheral region 110P’ is greater than 1μm. Other values are also possible.

With continued reference to FIG. 4A, a portion of the semiconductor wafer 1200 directly underlying the portion of the first semiconductor die 110 in the peripheral region 110P may also be removed to form a semiconductor wafer 1200’ having a recess 120R. The recess 120R may be a close loop surrounding the first semiconductor die 110” in a top view (not shown). The depth of the recess 120R may vary depending on the process and product requirements as long as the non-bond areas NB1 (labeled in FIG. 2A) of the bonded structure are removed. The width of the recess 120R may correspond to the width of the removed portion of the first semiconductor die 110. By removing the non-bond areas NB1 (labeled in FIG. 2A) in the first semiconductor die and the semiconductor wafer, the rest of the bonding interface IF10’ may remain well-bonded. For example, the bottommost part of the recess 120R reaches the interface of the second bonding structure 124’ and the second interconnect structure 123’ or may extend into the second interconnect structure 123’. In the illustrated embodiment, the recess 120R is defined by the inner sidewalls (124V1 and 124V2) of the second bonding dielectric layer 1241’ of the second bonding structure 124’, the inner sidewalls (123V1 and 123V2) of the second dielectric layer 1231’ of the second interconnect structure 123’, and the upper surface 1231t of the second dielectric layer 1231’. In other embodiments where the bottom of the recess 120R reaches the second bonding structure without extending into the second interconnect structure, the recess 120R is defined by the inner sidewalls (124V1, 124V2, 123V1, and 123V2) and the upper surface of the second bonding dielectric layer. In some embodiments, the inner sidewalls (124V1 and 123V1) are substantially aligned (or coplanar) with the continuous sidewall 110W of the first semiconductor die 110”.

Referring to FIG. 4B and with reference to FIG. 4A and FIGS. 2C-2D, an insulating encapsulant 232 may be formed on the semiconductor wafer 1200’ to cover the first semiconductor die 110”. The material and the forming method of the insulating encapsulant 232 may be similar to the insulating encapsulant 132 described in FIG. 2C, and thus, the details thereof are not repeated herein. The insulating encapsulant 232 may extend along the continuous sidewall 110W of the first semiconductor die 110” and fill the recess 120R of the semiconductor wafer 1200’. For example, the insulating encapsulant 232 is in physical contact with the inner sidewalls (124V1, 124V2, 123V1, and 123V2) of the second bonding dielectric layer 1241’ and the second dielectric layer 1231’ and the upper surface 1231t of the second dielectric layer 1231’ that define the recess 120R. A planarization process (e.g., CMP, grinding, etching, combinations thereof, or the like) is optionally performed to planarize the insulating encapsulant 232 and the first semiconductor die 110”. In some embodiments, the back side 111b of the first semiconductor die 110” and top surface 232t of the insulating encapsulant 232 are substantially level (or coplanar), within process variations. Since the non-bond areas NB1 (labeled in FIG. 2A) are removed before forming the insulating encapsulant 232, no delamination/crack exists in the remaining bonding interface IF10’. In this manner, the likelihood of delamination/crack propagation caused by the stress induced during the formation of the insulating encapsulant 232 may be reduced or eliminated.

In some embodiments, a thinning process (e.g., grinding, CMP, etching, combinations thereof, or the like) is performed on the back side of the semiconductor wafer 1200’ until at least a portion of the second ends 125b of the TSVs 125 is accessibly exposed. The thinning process may be similar to the process described in FIG. 2C, and thus the details thereof are not repeated herein. In some embodiments, the redistribution structure 150 and the conductive terminals 142 are sequentially formed on the back side of the semiconductor wafer 1200’ and the second ends 125b of the TSVs 125. The details of the redistribution structure 150 and the conductive terminals 142 are described in FIG. 2D and not repeated herein. In alternative embodiments, the redistribution structure 150 is replaced with the UBM pads to directly couple the conductive terminals 142 to the TSVs 125.

Referring to FIG. 4C and with reference to FIG. 4B and FIGS. 2E-2F, a singulation process is optionally performed by cutting along the scribe lanes SL1 to form individual semiconductor structure 10D. In some embodiments, the scribe lanes SL1 vertically pass through the recess 120R of the semiconductor wafer 1200’, and the cutting tool (e.g., a saw, a blade, or the like) may travel through the insulating encapsulant 232 and the semiconductor wafer 1200’. For example, the resulting semiconductor structure 10D includes a first tier 201 stacked upon a second tier 202, where the first tier 201 includes the first semiconductor die 110” and the insulating encapsulant 232’ laterally covering the first semiconductor die 110”, and the second tier 202 includes the second semiconductor die 120’ formed by simulating the semiconductor wafer 1200’, the redistribution structure 150 underlying the second semiconductor die 120’, and the conductive terminals 142 electrically coupled to the second semiconductor die 120’ through the redistribution structure 150. After the singulation process, the maximum lateral dimension LX1 of the first semiconductor substrate 111 is less than the maximum lateral dimension LM2 of the second semiconductor die 120. The maximum lateral dimensions of the first interconnect structure 113, the first bonding structure 114, and the second bonding structure 124 may be substantially equal to the maximum lateral dimension LX1 of the first semiconductor substrate 111. The insulating encapsulant 232’ may extend vertically into the second tier 202 and beyond the bonding interface IF10’. For example, the insulating encapsulant 232’ extends along the continuous sidewall 110W of the first semiconductor die 110” and the inner sidewalls (124V1 and 123V1) of the second bonding structure 124’ and the second interconnect structure 123’.

In some embodiments, the singulated sidewall 232W of the insulating encapsulant 232’ is substantially aligned (or coplanar) with the singulated sidewall of the second semiconductor die 120’. In the embodiments where the scribe lanes SL1 vertically pass through the recess 120R of the semiconductor wafer 1200’, the singulated sidewall of the second semiconductor die 120’ includes the outer sidewall 123W1 of the second interconnect structure 123’, the outer sidewall 121W of the second semiconductor substrate 121, and the outer sidewall 150W of the redistribution structure 150 (if exists). The locations of the scribe lanes SL1 labeled in FIG. 4B may be adjusted depending on process and product requirements. In alternative embodiments, the scribe lanes SL1 vertically pass through the area outside the recess 120R, and thus after the singulation process, the recess 120R filled with the insulating encapsulant 232 may remain in the resulting semiconductor structure. The semiconductor structure 10D is optionally mounted on the package substrate 20 (see FIG. 2F) using the conductive terminals 142 to form an IC package.

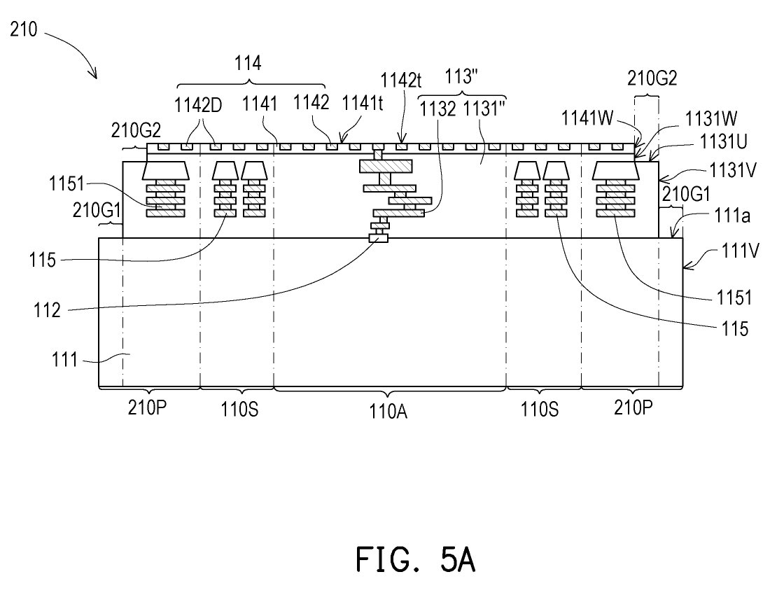

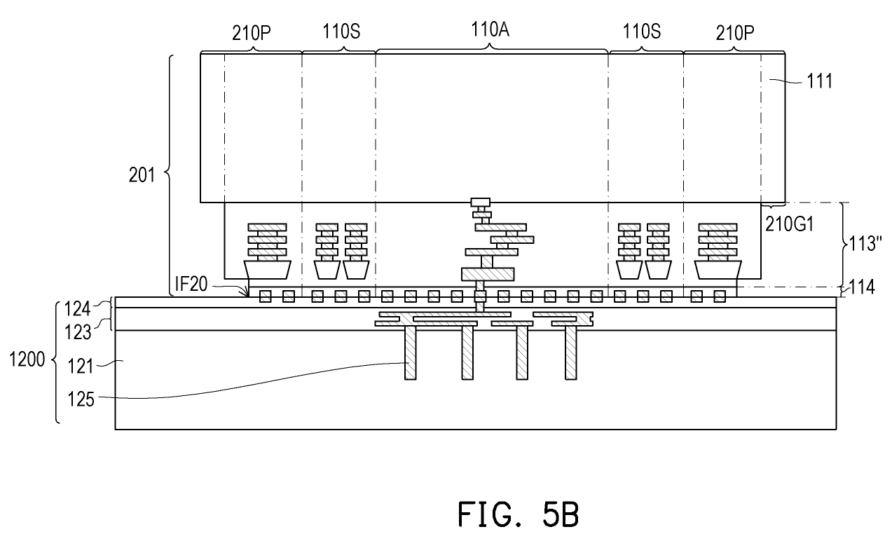

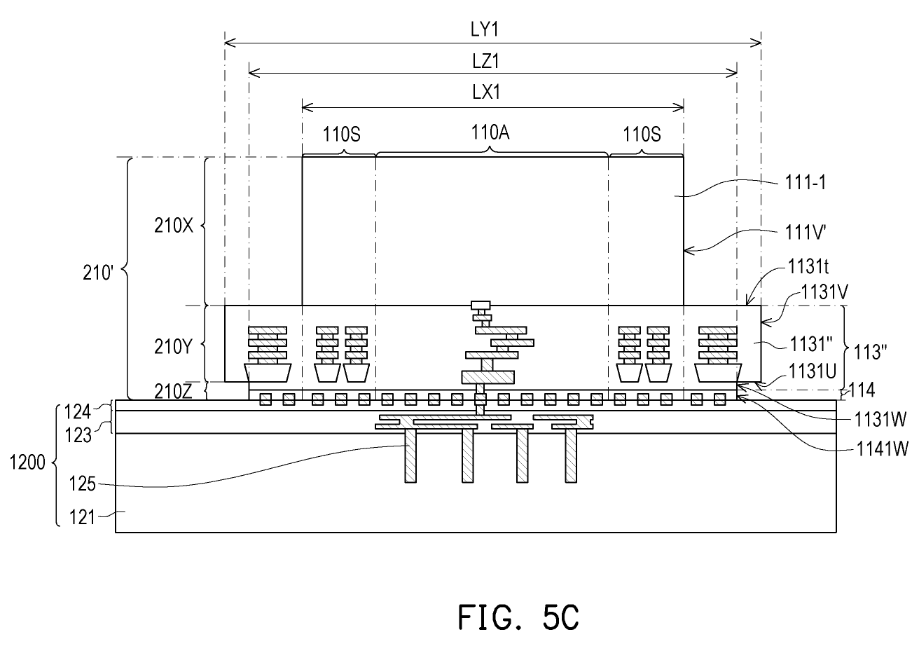

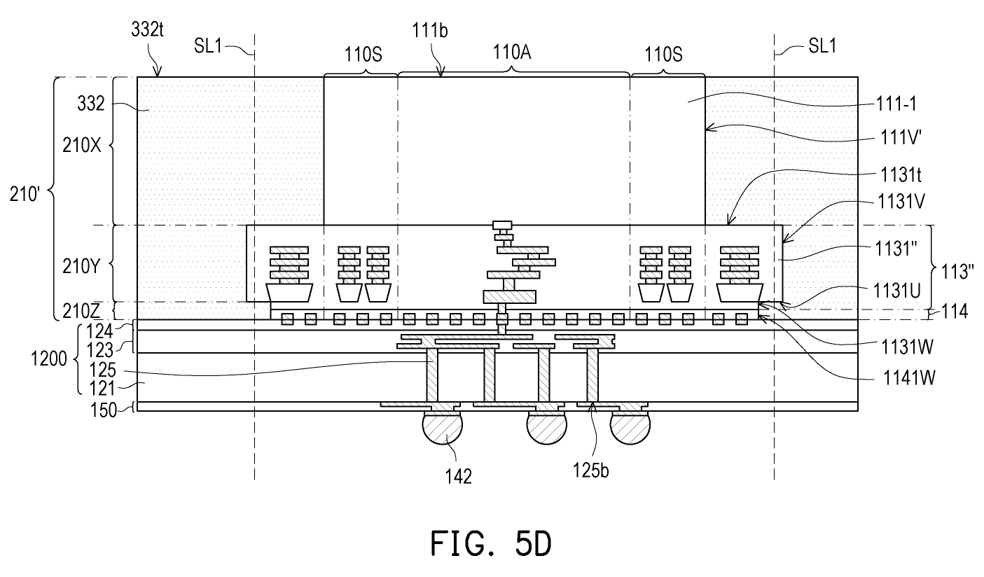

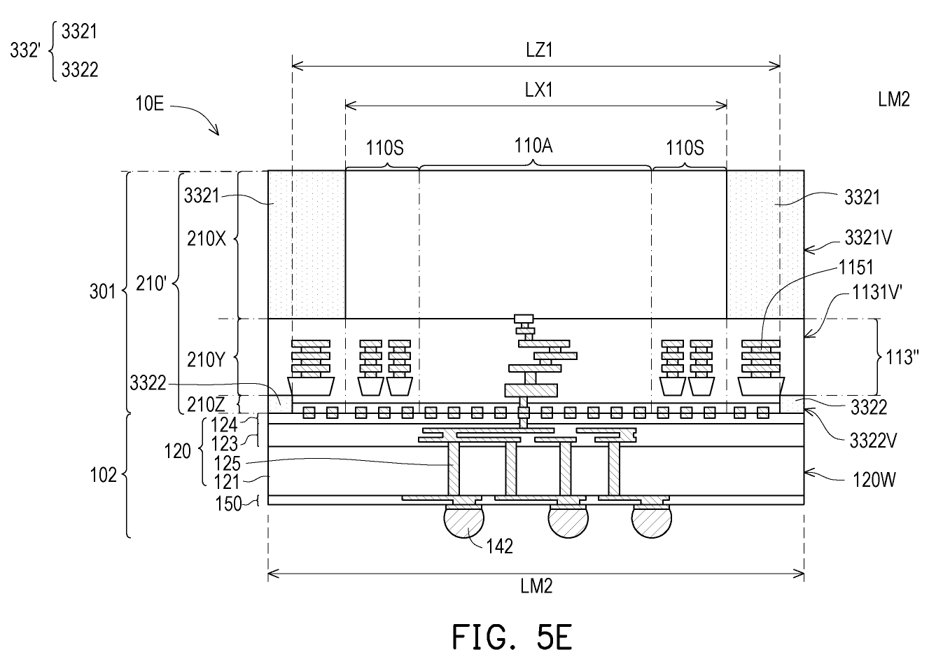

FIG. 5A illustrates a schematic cross-sectional view of a first semiconductor die, in accordance with some embodiments. It should be noted that FIG. 5A is provided for illustrative purposes only, and the first semiconductor die may utilize fewer or additional elements according to some embodiments. Unless specified otherwise, the first semiconductor die in FIG. 5A is essentially the same as the first semiconductor die described in FIG. 1A. The details of the first semiconductor die shown in FIG. 5A may be found in the discussion of the previous embodiments.

Referring to FIG. 5A and with reference to FIG. 1A, a first semiconductor die 210 may be similar to the first semiconductor die 110 describe din FIG. 1A, except that the first semiconductor dies 210 includes a first ledge 210G1 and a second ledge 210G2 which are disposed in the peripheral region 210P. The first semiconductor dies 210 may have a stepped sidewall. For example, the first semiconductor die 210 is formed in a wafer (not shown), which may include different die regions that are singulated in subsequent steps to form a plurality of first semiconductor dies 210. To perform a singulation process for forming the first semiconductor die 210, a shallow recess may be formed in the scribe line regions of the semiconductor wafer by etching or other suitable recessing process, thereby forming the sidewall 1141W of the first bonding dielectric layer 1141. If the shallow recess is deep enough to reach the first interconnect structure 113”, the first sidewall 1131W1 of the first dielectric layer 1131” and the first surface 1131U of the first dielectric layer 1131” connected to the first sidewall 1131W1 are also formed. Next, a grooving process (e.g., laser grooving, plasma dicing, or the like) may be performed on the semiconductor wafer and through the shallow recess, thereby forming the groove connected to the recess. For example, the groove penetrates through the first dielectric layer 1131”, and the second ledge 210G2 having the second sidewall 1131V of the first dielectric layer 1131” is formed. In some embodiments, the grooving process stops until the front side 111a of the first semiconductor substrate 111 is accessibly exposed. Subsequently, a sawing process may be performed on the semiconductor wafer to fully separate the die regions from one another to form individual first semiconductor dies 210. The sawing process may be performed through the shallow recess and the underlying groove in the scribe line regions, and the first ledge 210G1 having the sidewall 111V of the first semiconductor substrate 111 is formed.

The aforementioned steps for forming the first semiconductor die 210 are merely an example, and other suitable methods for forming the first semiconductor die 210 having the stepped sidewall profile may be used. The lateral dimensions (e.g., the widths) of the first and second ledges (210G1 and 210G2) may vary and may depend on the width of the groove formed by the grooving process and the blade which is used to perform the sawing process. The lateral dimensions of the first and second ledges (210G1 and 210G2) construe no limitation in the disclosure. Due to differences in the processes of recessing/grooving/sawing, sidewalls/surfaces of different regions of the first semiconductor die 210 may have different roughness. For example, the sidewalls/surfaces (1131W, 1131U, 1131V, and 111a) formed by recessing/grooving are smoother than the sidewall 111V formed by sawing. In some embodiments, a surface roughness of the sidewalls/surfaces (1131W, 1131U, 1131V, and 111a) is less than that of the sidewall 111V.

FIGS. 5B-5E illustrate schematic cross-sectional views of intermediate steps during a process for forming a semiconductor structure, in accordance with some embodiments. Unless specified otherwise, the materials and the formation methods of the components in these embodiments are essentially the same as the like components, which are denoted by like reference numerals in the embodiments shown in FIGS. 2A through 2E. The details regarding the formation process and the materials of the components shown in FIGS. 5B-5E may be found in the discussion of the previous embodiments.

Referring to FIG. 5B and with reference to FIG. 5A and FIG. 2A, the first semiconductor die 210 may be bonded to the semiconductor wafer 1200. The bonding process of the first semiconductor die 210 and the semiconductor wafer 1200 may be similar to the process described in FIG. 2A, and thus, the details thereof are not repeated herein. For example, the first bonding structure 114 of the first semiconductor die 210 may be bonded to the second bonding structure 124 of the semiconductor wafer 1200, and the bonding interface IF20 of the first semiconductor die 210 and the semiconductor wafer 1200 may be substantially flat and planar.

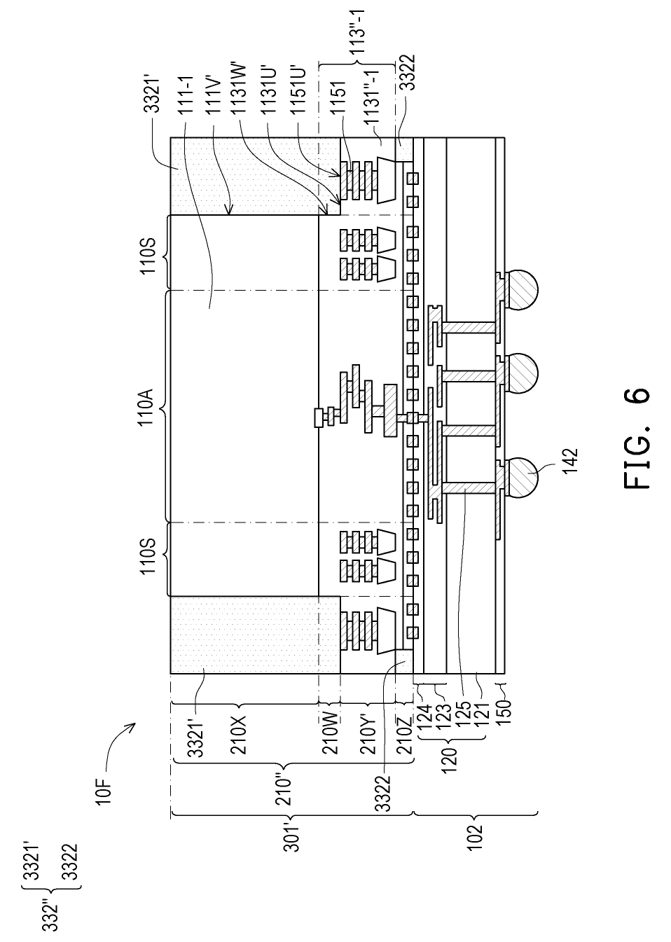

Referring to FIG. 5C and with reference to FIG. 5B and FIG. 2B, a portion of the first semiconductor die 210 in the peripheral region 210P may be removed by any suitable method to form a first semiconductor die 210’. For example, a photoresist (not shown) is formed on the bonded structure and covers the back side of the first semiconductor substrate 111 by spin-coating, spray-coating, or any suitable deposition process, and then a patterning process may be performed on the photoresist to form an opening by lithography or the like, where the opening of the photoresist may accessibly expose a portion of the first semiconductor substrate 111 to be removed. Next, the portion of the first semiconductor substrate 111 exposed by the opening of the photoresist may be removed by, for example, etching or any suitable removal process. Subsequently, the photoresist may be removed. In some embodiments, only the portion of the first semiconductor substrate 111 in the peripheral region 210P is removed to accessibly expose the second surface 1131t of the first dielectric layer 1131” which is opposite to the first surface 1131U. In alternative embodiments, not only the portion of the first semiconductor substrate 111 in the peripheral region 210P, but also a portion of the first dielectric layer 1131” directly underlying the portion of the first semiconductor substrate 111 in the peripheral region 210P is removed, as will be described later in accompanying with FIG. 6.

As shown in FIG. 5C, the first semiconductor die 210’ may include a first portion 210X, a second portion 210Y underlying the first portion 210X, and a third portion 210Z underlying the second portion 210Y and bonded to the semiconductor wafer 1200. For example, the first portion 210X is the remaining first semiconductor substrate 111-1, the second portion 210Y is a part of the first interconnect structure 113”, and the third portion 210Z includes the rest of the first interconnect structure 113” and the underlying first bonding structure 114. In some embodiments, the second portion 210Y is laterally protruded from the first portion 210X and the third portion 210Z, and the third portion 210Z is wider than the first portion 210X. For example, the lateral dimension LY1 of the second portion 210Y is greater than the lateral dimension LZ1 of the third portion 210Z, and the lateral dimension LZ1 of the third portion 210Z is greater than the lateral dimension LX1 of the first portion 210X. The sidewall 111V’ of the first portion 210X may be laterally displaced from the sidewall 1131V of the second portion 210Y, and the sidewalls (111V’ and 1131V) may be laterally displaced from the sidewall (1131W and 1141W) of the third portion 210Z.

Referring to FIG. 5D and with reference to FIG. 5C and FIG. 2C-2D, an insulating encapsulant 332 may be formed on the semiconductor wafer 1200 to cover the first semiconductor die 210’. The material and the forming method of the insulating encapsulant 332 may be similar to the insulating encapsulant 132 described in FIG. 2C, and thus, the details thereof are not repeated herein. A planarization process (e.g., CMP, grinding, etching, combinations thereof, or the like) is optionally performed to planarize the insulating encapsulant 332. In some embodiments, the back side 111b of the first semiconductor substrate 111-1 and the top surface 332t of the insulating encapsulant 332 are substantially level (or coplanar), within process variations. The insulating encapsulant 332 may have portions with different widths which correspond to the first/second/third portions of the first semiconductor die 210’. The insulating encapsulant 332 may extend along the stepped sidewall of the first semiconductor die 210’. For example, the insulating encapsulant 332 is in physical contact with the sidewall 111V’ of the first semiconductor substrate 111-1, the first and second surfaces (1131Uand 1131t) and the first and second sidewalls (1131W and 1131V) of the first dielectric layer 1131”, and the sidewall 1141W of the first bonding structure 114.

In some embodiments, a thinning process (e.g., grinding, CMP, etching, combinations thereof, or the like) is performed on the back side of the semiconductor wafer 1200 until at least a portion of the second ends 125b of the TSVs 125 is accessibly exposed. The thinning process may be similar to the process described in FIG. 2C, and thus the details thereof are not repeated herein. In some embodiments, the redistribution structure 150 and the conductive terminals 142 are sequentially formed on the back side of the semiconductor wafer 1200 and the second ends 125b of the TSVs 125. The details of the redistribution structure 150 and the conductive terminals 142 are described in FIG. 2D and not repeated herein. In alternative embodiments, the redistribution structure 150 is replaced with the UBM pads to directly couple the conductive terminals 142 to the TSVs 125.

Referring to FIG. 5E and with reference to FIG. 5D and FIGS. 2E-2F, a singulation process is optionally performed by cutting along the scribe lanes SL1 to form individual semiconductor structure 10E. In some embodiments, the scribe lanes SL1 vertically pass through the periphery of the first semiconductor die 210’. In such cases, at least a periphery of the second portion 210Y of the first semiconductor die 210’ may be removed after the singulation process. The portion of the insulating encapsulant 332 laterally surrounding the second portion 210Y of the first semiconductor die 210’ may be removed during the singulation process, and the rest of the insulating encapsulant 332 laterally surrounding the first portion 210X and the third portion 210Z of the first semiconductor die 210’ may remain after the singulation process. The locations of the scribe lanes SL1 labeled in FIG. 5D may be adjusted depending on process and product requirements. In some other embodiments, the scribe lanes SL1 only pass through the insulating encapsulant 332 and the underlying semiconductor wafer 1200 without passing through the first semiconductor die 210’, and thus the first/second/third portions (210X/210Y/210Z) of the first semiconductor die 210’ remain covered by the insulating encapsulant 332 after the singulation process. In alternative embodiments, the scribe lanes SL1 vertically pass through the additional seal rings 1151, and thus the additional seal rings 1151 are cut during the singulation process, as described and shown in FIG. 3B.

In some embodiments, the semiconductor structure 10E includes a first tier 301 stacked upon the second tier 102, where the first tier 301 includes the first semiconductor die 210’ and the insulating encapsulant 332’ laterally covering the first semiconductor die 210’, and the second tier 102 includes the second semiconductor die 120 formed by singulating the semiconductor wafer 1200, the redistribution structure 150 underlying the second semiconductor die 120, and the conductive terminals 142 electrically coupled to the second semiconductor die 120 through the redistribution structure 150. After the singulation process, the maximum lateral dimension LX1 of the first semiconductor substrate 111-1 of the first semiconductor die 210’ is less than the maximum lateral dimension LM2 of the second semiconductor die 120. The maximum lateral dimension of the first interconnect structure 113” may be substantially equal to the maximum lateral dimension LM2 the second semiconductor die 120. The insulating encapsulant 332’ may include a first portion 3321 laterally covering the first portion 210X of the first semiconductor die 210’ and a second portion 3322 laterally covering the third portion 210Z of the first semiconductor die 210’. The first portion 3321 and the second portion 3322 of the insulating encapsulant 332’ may be vertically separated from each other by the second portion 210Y of the first semiconductor die 210’. The singulated sidewalls (3321V and 3322V) of the first and second portions (3321 and 3322) of the insulating encapsulant 332’ may be substantially aligned (or coplanar) with the singulated sidewall 1131V’ of the second portion 210Y of the first semiconductor die 210’ and the singulated sidewall 120W of the second semiconductor die 120, within process variations. The semiconductor structure 10Eis optionally mounted on the package substrate 20 (see FIG. 2F) using the conductive terminals 142 to form an IC package.

FIG. 6 illustrates schematic cross-sectional views of a semiconductor structure, in accordance with some embodiments. Unless specified otherwise, the materials and the formation methods of the components in these embodiments are essentially the same as the like components, which are denoted by like reference numerals in the embodiments shown in FIG. 5E and FIGS. 3A. The details of the components shown in FIG. 6 may be found in the discussion of the previous embodiments.

Referring to FIG. 6 and with reference to FIG. 5E and FIG. 3A, a semiconductor structure 10F shown in FIG. 6 is similar to the semiconductor structure 10E shown in FIG. 5E, except that the first semiconductor die 210” of the first tier 301’ includes a fourth portion 210W vertically interposed between the first portion 210X and the second portion 210Y’, and the additional seal ring 1151 in the second portion 210Y’ is in direct contact with the insulating encapsulant 332”. The fourth portion 210W of the first semiconductor die 210” may have a lateral dimension substantially equal to the lateral dimension of the first portion 210X and less than the lateral dimension of the second portion 210Y’. For example, the fourth portion 210W is a part of the first interconnect structure 113”-1, and the second portion 210Y’ includes the rest part of the first interconnect structure 113’-1. The second portion 210Y’ may be laterally protruded from the fourth portion 210W. The additional seal ring 1151 may be disposed in the second portion 210Y’.

The processes of forming the first semiconductor die 210” may be similar to the processes described in FIG. 3A. For example, during the process of partially removing the first semiconductor die 210 as described in FIG. 5C, a portion of the first interconnect structure 113” underlying the portion of the first semiconductor substrate 111 in the peripheral region 210P (labeled in FIG. 5B) is also removed until at least a portion of the additional seal ring 1151 is accessibly exposed by the first dielectric layer 1131”-1. The additional seal ring 1151 may act as a stop layer during the removal process. In some embodiments, the upper surface 1131U’ of the first dielectric layer 1131”-1 and the upper surface 1151U’ of the additional seal ring 1151 are substantially leveled (or coplanar), within process variations. In some embodiments, the upper surface 1151U’ of the additional seal ring 1151 is protruded from the upper surface 1131U’ of the first dielectric layer 1131”-1. The sidewall 1131W’ of the first dielectric layer 1131”-1 connected to the upper surface 1131U’ may be substantially leveled (or coplanar) with the sidewall 111V’ of the first semiconductor substrate 111-1. The first portion 3321’ of the insulating encapsulant 332” may extend along the sidewalls (111V’ and 1131W’) of the first portion 210X and the fourth portion 210W. The first portion 3321’ of the insulating encapsulant 332” may be in physical contact with the upper surface 1131U’ of the first dielectric layer 1131”-1 and the upper surface 1151U’ of the additional seal ring 1151. The semiconductor structure 10F is optionally mounted on the package substrate 20 (see FIG. 2F) using the conductive terminals 142 to form an IC package.

Embodiments may have one or a combination of the following features and/or advantages. By removing a portion of the bonded structure corresponding to the non-bond areas in the bonded structure prior to the formation of the insulating encapsulant, the risk of delamination propagation in the bonded structure during the formation of the insulating encapsulant may be reduced or eliminated. For example, the step of removing the portion of the bonded structure includes removing a peripheral portion of the first semiconductor die. This may help to reduce the stress applied to the first semiconductor die during the formation of the insulating encapsulant, and the adhesion of the first semiconductor die and semiconductor wafer may be improved. In some embodiments, a portion of the semiconductor wafer directly bonded to the peripheral portion of the first semiconductor die is also removed to ensure the non-bond area does not exist in the bonded structure before forming the insulating encapsulant. In some embodiments, the first semiconductor die includes one or more ledge(s) which may provide a stepped profile, which can be adhered to the second semiconductor die by the insulating encapsulant to reduce delamination defects in the bonded structure. Accordingly, a semiconductor structure with reduced defects, improved reliability, and improved yield may be achieved.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

According to some embodiments, a semiconductor structure includes a first semiconductor die, a second semiconductor die underlying and bonded to the first semiconductor die, and an insulating encapsulant disposed over the second semiconductor die. The first semiconductor die includes a semiconductor substrate and an interconnect structure underlying the semiconductor substrate. A maximum lateral dimension of the semiconductor substrate of the first semiconductor die is less than that of the second semiconductor die. The insulating encapsulant at least laterally surrounds the semiconductor substrate of the first semiconductor die.

According to some embodiments, a semiconductor structure includes a first semiconductor die, a second semiconductor die underlying and bonded to the first semiconductor die, and an insulating encapsulant disposed over the second semiconductor die. The first semiconductor die includes a functional region, a seal ring region surrounding the functional region, and a peripheral region surrounding the seal ring region. The peripheral region of the first semiconductor die is in physical contact with the insulating encapsulant and includes a sidewall substantially aligned with a sidewall of the second semiconductor die.

According to some embodiments, a manufacturing method of a semiconductor structure includes: performing a bonding process to bond a first semiconductor die to a second semiconductor die, wherein after the bonding process, a first sidewall of the first semiconductor die is substantially leveled with a second sidewall of the second semiconductor die; and forming an insulating encapsulant over the second semiconductor die to laterally surround the first semiconductor die.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A manufacturing method of a semiconductor structure, comprising:
performing a bonding process to bond a first semiconductor die to a second semiconductor die;
forming an insulating encapsulant over the second semiconductor die to surround the first semiconductor die; and
performing a singulation process to at least dice the insulating encapsulant and the second semiconductor die, wherein at least one of the first semiconductor die and the second semiconductor die comprises a first sidewall and a second sidewall laterally offset from the first sidewall.

2. The manufacturing method of claim 1, further comprising:
removing a portion of a semiconductor substrate of the first semiconductor die to expose a surface of an interconnect structure of the first semiconductor die after the step of performing the bonding process.

3. The manufacturing method of claim 2, wherein the step of forming the insulating encapsulant over the second semiconductor die to surround the first semiconductor die comprises:
forming the insulating encapsulant along the surface of the interconnect structure, a sidewall of the interconnect structure connected to the surface, and a sidewall of the semiconductor substrate.

4. The manufacturing method of claim 2, wherein:
the step of forming the insulating encapsulant over the second semiconductor die to surround the first semiconductor die comprises:
forming the insulating encapsulant on the surface of the interconnect structure to extend along a sidewall of the semiconductor substrate; and
after the step of performing the singulation process, the insulating encapsulant is separated from the second semiconductor die by the interconnect structure in a thickness direction of the second semiconductor die.

5. The manufacturing method of claim 2, wherein the step of performing the singulation process comprises:
dicing the insulating encapsulant, the interconnect structure of the first semiconductor die, and the second semiconductor die, wherein the first sidewall is a sidewall of the semiconductor substrate of the first semiconductor die, and the second sidewall is a singulated sidewall of the interconnect structure of the first semiconductor die.

6. The manufacturing method of claim 2, wherein:
after the step of removing the portion of the semiconductor substrate of the first semiconductor die, exposing a top surface of a dielectric layer of the interconnect structure; and
after the step of forming the insulating encapsulant over the second semiconductor die to surround the first semiconductor die, interfacing the top surface and a sidewall of the dielectric layer of the interconnect structure connected to the top surface with the insulating encapsulant.

7. The manufacturing method of claim 2, wherein:
after the step of removing the portion of the semiconductor substrate of the first semiconductor die, exposing a top surface of a conductive feature of the interconnect structure; and
after the step of forming the insulating encapsulant over the second semiconductor die to surround the first semiconductor die, interfacing the top surface of the conductive feature of the interconnect structure with the insulating encapsulant.

8. The manufacturing method of claim 1, wherein the step of performing the singulation process comprises:
dicing the insulating encapsulant, a seal ring of an interconnect structure of the first semiconductor die, and the second semiconductor die, wherein singulated sidewalls of the insulating encapsulant, the seal ring, and the second semiconductor die are substantially leveled.

9. The manufacturing method of claim 1, wherein:
the step of performing the bonding process comprises:
forming a bonding interface of the first semiconductor die and the second semiconductor die by dielectric-to-dielectric bonding and metal-to-metal bonding; and
the step of performing the singulation process comprises:
dicing the bonding interface of the first semiconductor die and the second semiconductor die.

10. The manufacturing method of claim 1, further comprising:
removing a portion of the second semiconductor die to form a recess surrounding a bonding interface of the first semiconductor die and the second semiconductor die after the step of performing the bonding process.

11. The manufacturing method of claim 10, wherein the step of forming the insulating encapsulant over the second semiconductor die to surround the first semiconductor die comprises:
filling the recess with the insulating encapsulant.

12. The manufacturing method of claim 10, wherein the step of performing the singulation process comprises:
dicing the insulating encapsulant and the second semiconductor die, wherein the first sidewall is an inner sidewall of the second semiconductor die interfaced with the insulating encapsulant, and the second sidewall is a singulated sidewall of the second semiconductor die substantially leveled with a singulated sidewall of the insulating encapsulant.

13. A manufacturing method of a semiconductor structure, comprising:
bonding a first semiconductor die to a second semiconductor die;
removing a portion of the first semiconductor die or a portion of the second semiconductor die after the step of bonding the first semiconductor die to the second semiconductor die; and
forming an insulating encapsulant over the second semiconductor die to surround the first semiconductor die after the step of removing the portion of the first semiconductor die or the portion of the second semiconductor die.

14. The manufacturing method of claim 13, wherein the step of removing the portion of the first semiconductor die or the portion of the second semiconductor die comprises:
removing a portion of a semiconductor substrate of the first semiconductor die to expose an interconnect structure of the first semiconductor die.

15. The manufacturing method of claim 14, wherein the step of removing the portion of the first semiconductor die or the portion of the second semiconductor die further comprises:
removing a portion of the interconnect structure underlying the portion of the semiconductor substrate of the first semiconductor die.

16. The manufacturing method of claim 13, wherein the step of removing the portion of the first semiconductor die or the portion of the second semiconductor die comprises:
forming a recess on the second semiconductor die which surrounds a bonding interface of the first semiconductor die and the second semiconductor die.

17. The manufacturing method of claim 16, wherein the step of forming the insulating encapsulant over the second semiconductor die to surround the first semiconductor die comprises:
filling the recess with the insulating encapsulant, wherein a bottommost surface of the insulating encapsulant is formed between the bonding interface and a bottommost surface of the second semiconductor die.

18. A manufacturing method of a semiconductor structure, comprising:
bonding a first bonding structure of a first semiconductor die to a second bonding structure of a second semiconductor die; and
forming an insulating encapsulant over the second bonding structure of the second semiconductor die to surround the first semiconductor die, wherein a first portion of the insulating encapsulant is spaced apart from the second semiconductor die via the first bonding structure and an interconnect structure of the first semiconductor die overlying the first bonding structure in a thickness direction of the second semiconductor die.

19. The manufacturing method of claim 18, further comprising:
removing a portion of the first semiconductor die before the step of forming the insulating encapsulant, wherein:
the first semiconductor die comprises an interconnect structure overlying the first bonding structure and a semiconductor substrate overlying the interconnect structure, and
after the step of removing the portion of the first semiconductor die, the interconnect structure is wider than the semiconductor substrate.

20. The manufacturing method of claim 19, further comprising:
performing a singulation process to dice the insulating encapsulant, the interconnect structure of the first semiconductor die, and the second semiconductor die, wherein after the step of performing the singulation process, the insulating encapsulant comprises:
the first portion disposed on the interconnect structure and laterally interfaced with the semiconductor substrate; and
a second portion separated from the first portion in the thickness direction and interfaced with the first bonding structure and the second bonding structure.
